(19) United States
(12) Patent Application Publication
(10) Pub. No.: US 2011/0275216 A1
(43) Pub. Date: Nov. 10, 2011

(54) TWO STEP CHEMICAL-MECHANICAL POLISHING PROCESS

(75) Inventors: Chun Fu Chen, Taipei City (TW); Yung Tai Hung, Chiayi City (TW); Chin-Ta Su, Yunlin Country (TW); Ta-Hung Yang, Miaoli County (TW)

(73) Assignee: MACRONIX INTERNATIONAL CO., LTD.

(21) Appl. No.: 12/773,372

(22) Filed: May 4, 2010

(51) Int. Cl. H01L 21/463; H01L 21/465

(52) U.S. Cl. 438/693; 438/692; 257/E21.484; 257/E21.485

(57) ABSTRACT

A chemical mechanical polishing method includes employing a topologically selective slurry or an abrasive trapped or abrasive mounted pad in an initial polishing operation to provide a substantially planar topology of a polysilicon layer of a semiconductor wafer, and performing a second polishing operation to remove a portion of the polysilicon layer to expose discrete elements of the semiconductor wafer.

### TECHNOLOGICAL FIELD

Embodiments of the present invention relate generally to chemical-mechanical polishing (CMP) processes and, more particularly, relate to a two step slurry polishing process for providing improved planarity of polished semiconductor devices.

### BACKGROUND

Since the advent of computers, there has been a steady drive toward producing smaller and more capable electronic devices, such as computing devices, communication devices and memory devices. In order to reduce the size of such devices, while maintaining or improving their respective capabilities, the size of components within the devices must be reduced. Several of the components within electronic devices are made from semiconductor materials, which in some cases are provided via a structure called a semiconductor wafer.

In recent years, there have been numerous advances related to enhancing the ability of semiconductor device manufacturers to produce semiconductor devices with reduced dimensions. Reductions in semiconductor device dimensions may provide higher densities and improve performance of integrated circuits. In many electronic devices that employ integrated circuits, the integrated circuits may include millions of discrete elements such as transistors, resistors and capacitors that are built in close proximity to each other on a single wafer. In some cases, the close proximity of these elements can create undesirable effects such as parasitic capacitance or other performance degrading conditions. Accordingly, electrical isolation of elements on a common substrate in semiconductor devices is an important part of the fabrication process. However, a common problem that may be encountered in relation to providing isolation of structures is called pattern density effect. The pattern density effect may result in rough surface morphology even after polishing because of wide variations in the pattern density and dimensions of trenches or other isolation structures.

CMP combines both chemical action and mechanical forces and is commonly used to remove metal and dielectric overlayers in damascene processes, to remove excess oxide in shallow trench isolation steps, and to reduce topography across a dielectric region. Components required for CMP typically include a chemically reactive liquid medium in the form of a slurry and a polishing surface to provide the mechanical control required to approach planarity. The slurry may contain inorganic particles to enhance the reactivity and mechanical activity of the process. Typically, for dielectric polishing, the surface may be softened by the chemical action of the slurry, and then removed by the action of the particles.

A limitation of conventional CMP is its high dependency on pattern density, which results in a non-uniform planarization of large and small features. The non-uniform planarization is often referred to as with-in-wafer non-uniformity (WIW NU). As a result, over-polishing may be required to completely remove the polysilicon in field oxide or STI, and maintain polysilicon in active areas. Dishing can occur due to the higher removal rate of loose area compared to that of dense area during CMP. Dishing may cause polysilicon to recess below the STI surface and may contribute to potential device failure. FIG. 1 illustrates a potential problem that may be encountered according to a conventional Poly CMP operation. In this regard, for example, during a conventional Poly CMP operation, uneven removal rates of polysilicon may be experienced. For example, due to the pattern density effect, greater removal rates of polysilicon may be experienced in less dense regions (e.g., such as the area near periphery elements 14) and lower removal rates may be experienced in regions that are more densely populated with elements (e.g., such as the area near the array elements 12) such that planarity of the topography of the wafer is not fully realized and the WIW NU is relatively high.

Accordingly, it may be desirable to provide an improved CMP process that may provide a more planarized topology.

### BRIEF SUMMARY OF EXEMPLARY EMBODIMENTS

Embodiments of the present invention are therefore provided that may enable the provision of a planarized topology using an improved two step process. In this regard, rather than employing a silicon dioxide slurry in a first operation followed by a conventional CMP operation as is employed by a conventional two step CMP process such as the one described above, embodiments of the present invention may employ a first operation followed by a conventional CMP second operation in which the first operation utilizes a topologically selective slurry. In some examples, the topologically selective slurry may include a Cerium dioxide (CeO₂) slurry with additives aimed at planarizing the topology by providing rates of removal that increase non-linearly with the amount of pressure applied during the CMP process. Accordingly, the etching and removal rates achieved in the first operation may essentially be tailored to the amount of material to be removed in a given local area such that areas with more material to be removed to achieve planarity experience higher removal rates and areas with less material to be removed to achieve planarity experience lower removal rates. As a result, the combination of the topologically selective initial polishing process operation with the second operation, may result in wafer having a substantially planar topology and a relatively low WIW NU.

In some embodiments, the first operation may include the topologically selective slurry in combination with an abrasive trapped or abrasive mounted pad. However, in other example embodiments, the abrasive trapped abrasive mounted pad may be used without a slurry.

In an exemplary embodiment, a chemical mechanical polishing method includes employing a topologically selective slurry in a first polishing operation to provide a substantially planar topology of a polysilicon layer of a semiconductor wafer, and performing a second polishing operation to remove a portion of the polysilicon layer to expose discrete elements of the semiconductor wafer.

It is to be understood that the foregoing general description and the following detailed description are exemplary, and are not intended to limit the scope of the invention.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 illustrates an example of results that may be experienced from a conventional Poly CMP process;

FIG. 2A illustrates a wafer having a native oxide layer over a polysilicon layer prior to CMP operations according an exemplary embodiment of the present invention;

FIG. 2B illustrates the wafer of FIG. 2A after removal of the native oxide layer and a portion of the polysilicon layer responsive to a first CMP operation employing a topologically selective slurry according an exemplary embodiment of the present invention;

FIG. 2C illustrates the wafer of FIG. 2B after performance of a second CMP operation according an exemplary embodiment of the present invention;

FIG. 3 illustrates a graphic representation of the removal rate characteristic of the first poly CMP processing operation according an exemplary embodiment of the present invention;

FIG. 4 illustrates a recipe content for employing one exemplary two step Poly CMP process according to an exemplary embodiment of the present invention;

FIG. 5 is a chart illustrating advantages associated with the implementation of one exemplary embodiment of the present invention;

FIG. 6, which includes FIGS. 6A and 6B, illustrates an example polishing process including an abrasive trapped or abrasive mounted pad according to an exemplary embodiment of the present invention;

FIG. 7, which includes FIGS. 7A and 7B, illustrates another example polishing process including an alternative abrasive trapped or abrasive mounted pad according to an exemplary embodiment of the present invention; and

FIG. 8 is a block diagram describing a method for performing a two step Poly CMP process according to an exemplary embodiment of the present invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

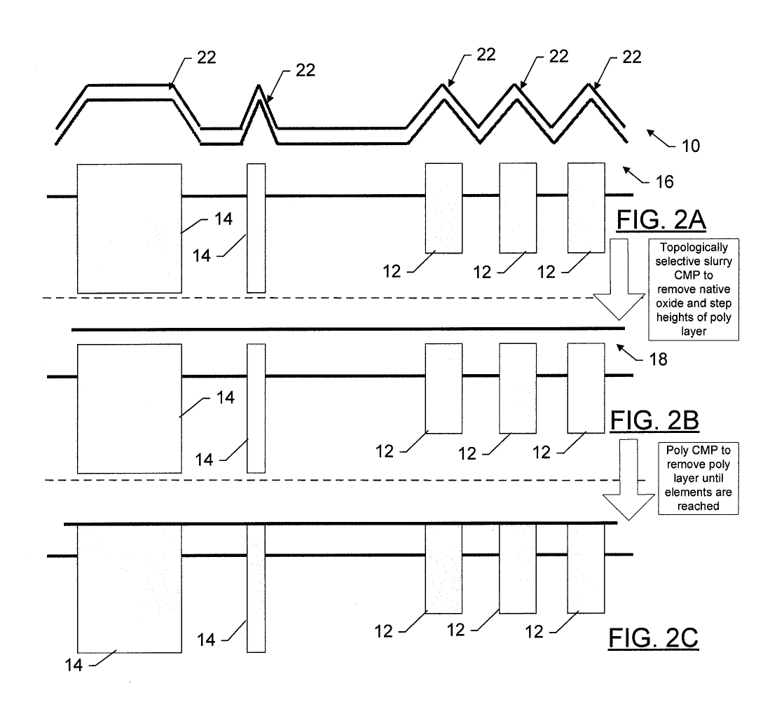

Some embodiments of the present invention may provide a mechanism by which improvements may be experienced in relation to the production of a semiconductor device wafer with substantially planar topography. In this regard, FIG. 2, which includes FIGS. 2A, 2B and 2C that are each separated by dashed lines, illustrates an example of a two-step Poly CMP process according an exemplary embodiment of the present invention. As shown in FIG. 2A, the structure to be processed may initially include a native oxide and polysilicon topology, including the native oxide layer 10 and the poly layer 16, which includes a plurality of steps of varying heights (defining stepped regions 22) at positions corresponding to the location of the elements of the semiconductor device wafer.

The structure shown in FIG. 2A is initially processed with a topologically selective (e.g., Cerium dioxide (CeO₂) slurry with additives) slurry so that the structure of FIG. 2B may be achieved. The native oxide layer 10 may be built up over polysilicon, sometimes referred to simply as poly, that is formatted naturally over various elements including array elements 12 and periphery elements 14. The conventional poly slurry has a relatively low removal rate for oxide films. Accordingly, by using the topologically selective slurry in a separate initial step, the oxide film of the native oxide layer 10 can be more efficiently removed (e.g., both native oxide and topology can be eliminated simultaneously). After removal of the native oxide layer 10 in the first CMP operation, a second CMP operation may be performed to remove portions of the poly layer 16 down to the array elements 12 and the periphery elements 14. As shown in FIG. 2B, by employing the Cerium dioxide (CeO₂) slurry with additives, a native oxide and substantially planar topography are achieved even prior to employing the second operation of poly CMP. As such, the intermediately processed poly layer 18 shown in FIG. 2B has the step heights from FIG. 2A substantially removed to planarize the intermediately processed poly layer 18. In particular, the topologically selective slurry is provided while the wafer is processed between the platen and the polishing head in order to remove material from the stepped regions 22 at a faster rate (e.g., a non-linearly faster rate) than the rate of removal from regions between the stepped regions 22. As a result, the substantially planar intermediately processed poly layer 18 shown in FIG. 2B is produced.

The second operation of poly CMP may then be performed in order to remove excess poly over the elements (e.g., array elements 12 and periphery elements 14). However, in some cases modifications beyond the scope of this disclosure may also be made to the second CMP operation.

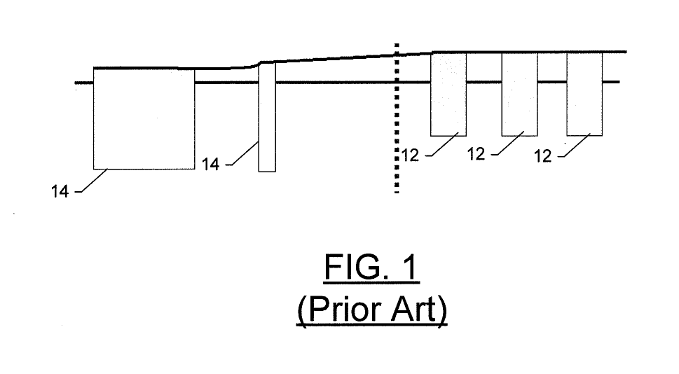

When the second operation of poly CMP is performed, the poly may be removed to the level of the elements as shown in FIG. 2C. However, unlike the finished product shown in FIG. 1, which shows the effects of uneven removal rates and results in a relatively high degree of WIW NU and non-planarity (and even erosion of some of the elements), the finished product of FIG. 2C shows a relatively high degree of uniformity and planarity.

Cerium dioxide (CeO₂) is an acid solution. Cerium dioxide (CeO₂) generally has a stronger bonding to Silicon dioxide (SiO₂) and thus, Cerium dioxide (CeO₂) is usually used to polish Silicon dioxide (SiO₂). The polysilicon surface of a wafer is hydrophobic and not hydrophilic and Cerium dioxide (CeO₂) generally has a relatively weak bonding to polysilicon. Accordingly, conventional Cerium dioxide (CeO₂) would typically not, by itself, remove polysilicon or be used to polish polysilicon. Accordingly, embodiments of the present invention employ a Cerium dioxide (CeO₂) slurry having additives that enhance the performance of the slurry such that the slurry acts as a topologically selective slurry. In this regard, for example, the slurry may include at least Cerium dioxide and silica formed in a slurry to provide an end result that a processed wafer is imparted with a planar topology. The silica (and potentially other additives as well) may enable the Cerium dioxide slurry to remove polysilicon. However, the inclusion of the Cerium dioxide may alter the normal properties of a typical silica slurry to provide the topological selectivity desired. The topologically selective nature of the slurry is evidenced by the way the first CMP process performed using the topologically selective slurry provides a uniform and planar resulting wafer topology even though the density of elements in the periphery and array may be vastly different. Thus, the Cerium dioxide (CeO₂) slurry is used to polish the step height of the polysilicon surface in a first CMP process and then general poly CMP is adopted to polish the polysilicon surface in the second CMP process.

The polysilicon layer on a typical semiconductor device wafer could be at least partially removed simply by rotating a pad material with some abrasive properties between a polishing head and a platen, on which the wafer may be positioned. The abrasives within the pad material may wear away the polysilicon layer with the rotation of the abrasive material over the wafer. Various slurries may be added to improve the process. In this regard, slurries may include further abrasives and chemical agents that may, for example, soften material and make the softened material more responsive or susceptible to being removed by the pad material. However, such conventional pad materials and slurries typically provide for rates of removal that increase substantially linearly with the increase of pressure between the polishing head and the platen. The removal rates are also typically increased in regions with a lower density of elements. The result is typically the same as provided in FIG. 1 with relatively high WIW NU.

To avoid the conventional drawbacks that occur in relation to non-uniformity and non-planarity, the Cerium dioxide and, silica slurry of embodiments of the present invention increases the susceptibility of the stepped regions (indicated by arrows 22 in FIG. 2A) to being removed during the first CMP process (i.e., the initial CMP process employing the topologically selective slurry). The increased susceptibility of the stepped regions to removal provides topological selectivity with respect to the initial CMP processing performed according to embodiments of the present invention. In other words, the stepped regions that are higher than other regions on the surface of the wafer are worn away more rapidly in order to provide a substantially planar poly surface over the entire wafer after initial processing. After the topologically selective Cerium dioxide and silica slurry of embodiments of the present invention is employed to provide a planarized wafer, the use of a second poly CMP processing operation is likely to provide a substantially planar and uniform wafer like the one shown in FIG. 2C. Accordingly, some embodiments of the present invention may provide a WIW range of poly remaining of about 200 angstroms due to the performance of the Cerium dioxide and silica slurry of embodiments of the present invention in relation to topological selectivity.

In an exemplary embodiment, the planarization achieved via embodiments of the present invention may be provided using topology selectivity CeO₂ polishing. The Cerium within the slurry may act as an abrasive that provides a nonlinear rate of removal of material relative to the force applied to the wafer being polished. In this regard, for example, at regions where higher pressure is exerted on the surface of the wafer (e.g., at the stepped regions 22) the rate of removal for the slurry increases in a nonlinear fashion. The topology selective surfactant within CeO2 slurry congregated more easily at the valley region than stepped regions due to the relatively lower local pressure, and it may isolate the CeO2 abrasive and poly surface to result in low removal rate in the valley region. Thus, material is removed much faster in the stepped regions than in valley regions between the stepped regions. As an example, if the polishing head and the platen are substantially equidistant from each other, then the abrasive pad would tend to exert a higher pressure on the stepped regions than on other regions of the wafer. The interaction between the Cerium abrasives in the slurry and the stepped regions therefore results in a higher pressure exerted at the stepped regions and consequently more rapid removal (in a non-linear fashion) of the step heights until a more planarized surface is achieved. Moreover, the density of the elements beneath the poly does not necessarily impact the performance of the Cerium dioxide and silica slurry of embodiments of the present invention. Thus, relatively independent of element density, embodiments of the present invention increase surface planarity.

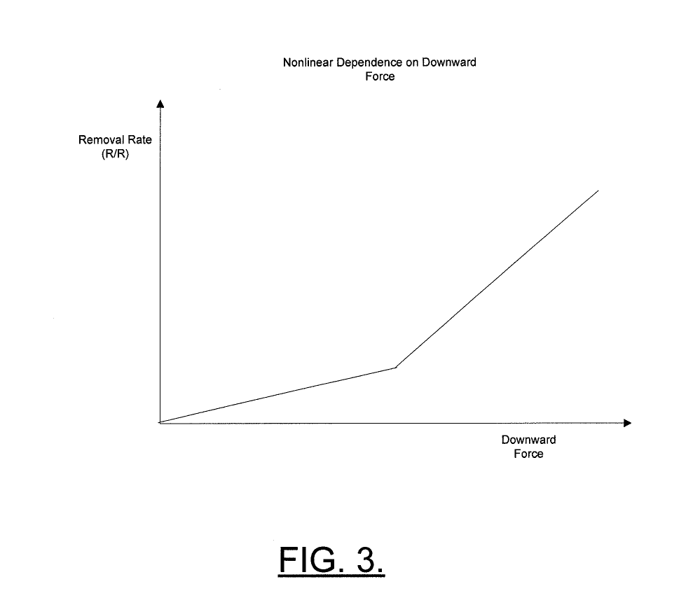

FIG. 3 illustrates a graphic representation of the removal rate characteristic of the first poly CMP processing operation. Accordingly, FIG. 3 illustrates how a topologically selective polishing operation may be achieved due to the force versus removal rate characteristics of the Cerium dioxide (CeO₂) slurry used in the first poly CMP processing operation. As shown in FIG. 3, the removal rate (R/R) increases non-linearly with the amount of downward force during the CMP polishing operation. Accordingly, a reduction in step heights is achieved and a high removal rate of topology results due to the abrasiveness of the Cerium dioxide (CeO₂) slurry and the direct touching of the polysilicon without surfactant protection. After the topology is eliminated by removal of the step heights, film selectivity may be further implemented with a different surfactant absorption property being employed.

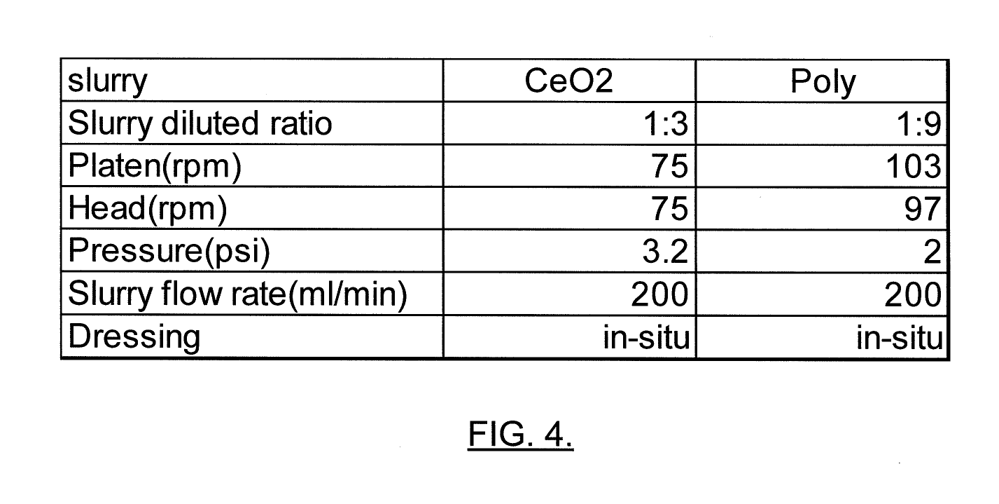

Although various different techniques could be employed in connection with employing embodiments of the present invention, one example technique or “recipe” is shown in FIG. 4, which shows data corresponding to characteristics of one exemplary Cerium dioxide (CeO₂) slurry that may be used in the initial, topologically selective, operation of CMP processing and characteristics of a conventional poly CMP used for a second operation of CMP processing in a two-step CMP process according to an exemplary embodiment of the present invention. However, it should be appreciated that other recipes are also possible for providing a topologically selective CMP process operation.

As shown in FIG. 4, in one embodiment, the slurry diluted ratio for the Cerium dioxide (CeO₂) slurry may be about 1:3, while the slurry diluted ration for the poly CMP slurry may be about 1:9. Platen RPM (revolutions per minute) for use with the Cerium dioxide (CeO₂) in the initial polishing operation may be about 75, while the platen may turn at about 103 RPM during the second operation of CMP processing. The polishing head may turn at about 75 RPM during the initial polishing operation and about 97 RPM during the second operation. Pressure in pounds per square inch (psi) may be 3.2 for the initial polishing operation and 2 for the second operation. Dressing may be performed in-situ in both instances and the slurry flow rate may be about 200 ml/min. However, as indicated above, the recipe of FIG. 4 is but one example set of criteria that may be employed in connection with an exemplary embodiment of the present invention. In an exemplary embodiment, a 98% water solution may include 1% by weight of Cerium dioxide (CeO₂) and 1% by weight of a C₃H₄O₂.H₃N solution. However, other solutions are also possible.

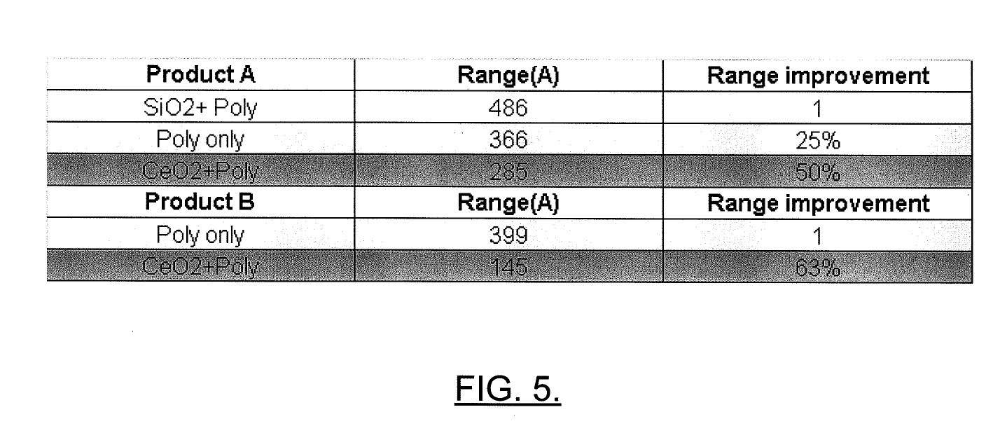

FIG. 5 is a chart illustrating advantages associated with the implementation of one exemplary embodiment of the present invention. In this regard, FIG. 5 shows different solutions used for polishing two products (product A and product B). As shown in FIG. 5, for product A, a polysilicon only slurry achieves a 25% improvement over a Silicon dioxide (SiO₂) and polysilicon solution. However, using a Cerium dioxide (CeO₂) slurry according to an example embodiment of the present invention may improve performance by 50%. Furthermore, for product B, the Cerium dioxide (CeO₂) slurry improves performance by 63% over a polysilicon only solution in terms of range improvement where range is considered the remaining polysilicon thickness (Max-Min) or remaining polysilicon thickness variation between dense and loose pattern densities.

According to an example embodiment as provided above, a combination of the topologically selective initial (or first) polishing process operation with a second CMP operation involving a slurry, may provide a resulting wafer having a substantially planar topology and a relatively low WIW NU. However, a relatively low WIW NU and substantially planar topology may also be provided by other alternative initial polishing process operations. For example, in some embodiments, the topologically selective slurry described above may be used in combination with an abrasive trapped or abrasive mounted pad during the initial polishing process operation. The abrasive trapped or abrasive mounted pad may include abrasives mounted or otherwise within the pad. In some alternative embodiments, the abrasive trapped or abrasive mounted polishing pad may be utilized during the initial polishing process operation without a slurry. In either of these two alternative cases, the second CMP operation described above may be used to complete the process.

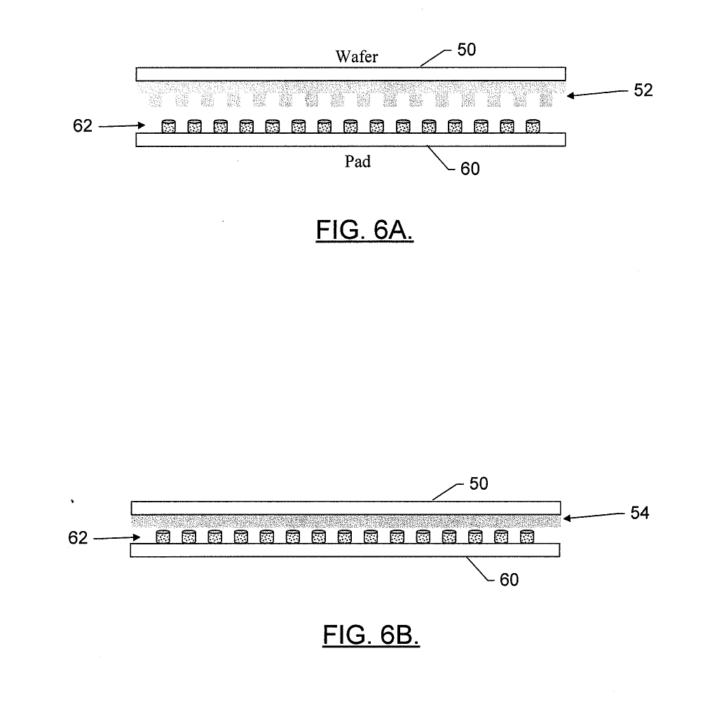

FIG. 6, which includes FIGS. 6A and 6B, illustrates an example polishing process including the abrasive trapped or abrasive mounted pad as described above. As shown in FIG. 6A a wafer 50 may initially have a poly topology 52 that includes non-uniformities. An abrasive trapped or abrasive mounted pad 60 according to an example embodiment may be implemented in an initial CMP operation (with or without the topologically selective slurry described above). Thereafter, poly may be removed to provide a more uniform poly topology 54 shown in FIG. 6B. In some embodiments, the abrasive trapped or abrasive mounted polishing pad 60 may comprise particles of, for example, SiO₂, CeO₂, ZrO₂, Al₂O₃, MnO₃, and/or the like. Thus, for example, the abrasive may be provided as a series of agglomerated particles mounted on the pad as shown by the abrasive particles 62 of FIGS. 6A and 6B. In some embodiments, the abrasive may be mounted on the pad in a column or pyramid shape to provide local planarization using 2-D polishing with or without a slurry. In some cases, TMAH (Tetramethyl ammonium hydroxide) and NH4OH may be applied for topology removal efficiency and defect reduction (TMAH and NH4OH can be applied during topology polishing or post CMP rinse/clean). Additionally, dry etching may be employed for higher portion elimination in the first step in some cases.

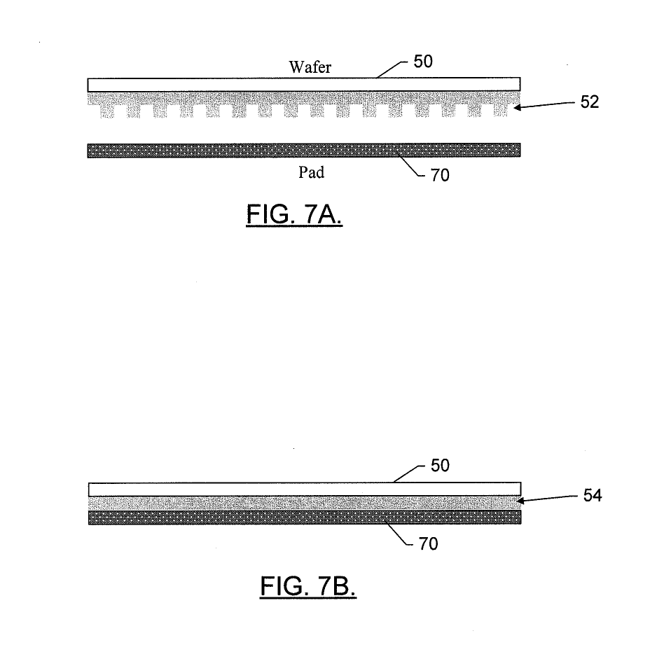

In an alternative embodiment, shown in FIG. 7, the particles may be embedded within a abrasive trapped or abrasive mounted pad 70. FIG. 7, which illustrates another example polishing process including an alternative abrasive trapped or abrasive mounted polishing pad also shows the wafer 50 having the poly topology 52 that includes non-uniformities. An abrasive trapped or abrasive mounted pad 70 according to an alternative example embodiment may be implemented in the initial CMP operation (with or without the topologically selective slurry described above). Thereafter, poly may be removed to provide a more uniform poly topology 54 shown in FIG. 7B. In some embodiments, the abrasive trapped or abrasive mounted polishing pad 70 may comprise particles of, for example, SiO₂, CeO₂, ZrO₂, Al₂O₃, MnO₃, and/or the like. Thus, for example, the abrasive may be provided as a series of embedded particles provided in the pad as shown in FIGS. 7A and 7B. In some embodiments, the abrasive may be embedded in the pad to provide local planarization using 2-D polishing with or without a slurry.

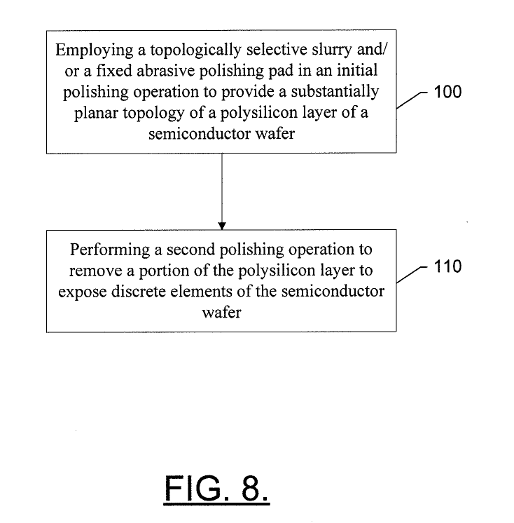

FIG. 8 illustrates a flow chart showing the processes performed in connection with an exemplary embodiment of the present invention in order to provide topological uniformity and planarity with respect to a polished semiconductor wafer. In this regard, a method of polishing a semiconductor wafer may include employing a topologically selective slurry and/or an abrasive trapped pad or abrasive mounted pad in an initial or first polishing operation of a CMP process at operation 100. The first polishing operation may remove a native oxide layer and at least a portion of a poly layer over semiconductor device elements. The portion of the polysilicon layer that is removed may include reduction of step heights within the polysilicon layer to substantially planarize the topology of the polysilicon layer. As such, for example, the first polishing operation may provide etching and removal rates that are tailored to the amount of material to be removed in a given local area such that areas with more material to be removed to achieve planarity experience higher removal rates and areas with less material to be removed to achieve planarity experience lower removal rates. As indicated above, the topologically selective slurry may be Cerium dioxide (CeO₂) slurry with silica and/or other additives. Furthermore, the topological selectivity may be provided by virtue of the non-linear increase in removal rate for the topologically selective slurry with increasing pressure. The topologically selective slurry may, in some cases, provide a rate of removal of polysilicon that is independent of the density of discrete elements of the semiconductor wafer in order to avoid the density pattern effect described above.

The method may further include performing a second polishing operation comprising a poly chemical-mechanical polishing operation at operation 110. As indicated above, the second polishing operation may be substantially similar to a conventional second CMP operation. In other words, the second polishing operation may employ a conventional poly slurry. Because the native oxide layer has been removed by the topologically selective slurry, the second polishing operation may be completed without a significant delay associated with removal of the native oxide layer, which a conventional poly slurry would typically be slow to remove. Furthermore, because the topologically selective slurry provides a planarized topology to the polysilicon layer that is to be removed by the second polishing operation, the result of the second polishing operation is also a planarized topology with relatively low variation and high uniformity WIW.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A chemical mechanical polishing method comprising:
employing a topologically selective slurry in a first polishing operation to provide a substantially planar topology of a polysilicon layer of a semiconductor wafer; and
employing a film selective slurry in a second polishing operation to remove a portion of the polysilicon layer to expose discrete elements of the semiconductor wafer.

2. The method of claim 1, wherein employing the topologically selective slurry comprises employing a slurry that provides a rate of removal during chemical mechanical polishing that increases non-linearly with increasing pressure.

3. The method of claim 1, wherein employing the topologically selective slurry comprises employing a slurry that provides a rate of removal of polysilicon that is independent of the density of discrete elements of the semiconductor wafer.

4. The method of claim 1, wherein employing the topologically selective slurry comprises employing a slurry that includes Cerium dioxide.

5. The method of claim 1, wherein employing the topologically selective slurry comprises employing a slurry that includes Cerium dioxide in combination with an additive for removal of polysilicon.

6. The method of claim 1, wherein employing the topologically selective slurry comprises employing a slurry that includes Cerium dioxide in combination with silica.

7. The method of claim 1, wherein employing the topologically selective slurry comprises performing the first polishing operation to provide etching and removal rates that are tailored to an amount of material to be removed in a given local area such that areas with more material to be removed to achieve planarity experience higher removal rates and areas with less material to be removed to achieve planarity experience lower removal rates.

8. The method of claim 7, wherein there is a non-linear relationship between the removal rates in areas with more material to be removed than the removal rates in areas with less material to be removed.

9. The method of claim 1, wherein the second polishing operation comprises polishing the semiconductor wafer to provide a with-in-wafer range of about 200 angstroms.

10. The method of claim 1, wherein the second polishing operation comprises polishing the semiconductor wafer using a poly slurry.

11. The method of claim 1, wherein employing the topologically selective slurry comprises performing the first polishing operation to remove both a native oxide layer and a portion of the polysilicon layer.

12. The method of claim 11, wherein removal of the portion of the polysilicon layer comprises removing discontinuities in height of the polysilicon layer.

13. The method of claim 1, wherein employing the topologically selective slurry comprises employing an abrasive trapped or abrasive mounted pad in connection with the employing of the topologically selective slurry.

14. A chemical mechanical polishing method comprising:
employing an abrasive trapped or abrasive mounted pad in a first polishing operation to provide a substantially planar topology of a polysilicon layer of a semiconductor wafer; and
performing a second polishing operation to remove a portion of the polysilicon layer to expose discrete elements of the semiconductor wafer.

15. The method of claim 14, wherein employing the abrasive trapped or abrasive mounted pad comprises employing the abrasive trapped or abrasive mounted pad without a slurry.

16. The method of claim 14, wherein employing the abrasive trapped or abrasive mounted pad comprises employing the abrasive trapped or abrasive mounted polishing pad in combination with a slurry.

17. The method of claim 14, wherein employing the abrasive trapped or abrasive mounted pad comprises employing the abrasive trapped or abrasive mounted polishing pad having embedded abrasive particles of SiO₂, CeO₂, ZrO₂, Al₂O₃, or MnO₃.

18. The method of claim 14, wherein employing the abrasive trapped or abrasive mounted pad comprises employing the abrasive trapped or abrasive mounted polishing pad having a series of column shaped abrasive particles of SiO₂, CeO₂, ZrO₂, Al₂O₃, or MnO₃ mounted on the abrasive polishing pad.

19. The method of claim 14, wherein employing the abrasive trapped or abrasive mounted pad comprises employing the abrasive trapped or abrasive mounted polishing pad having a series of triangle shaped abrasive particles of SiO₂, CeO₂, ZrO₂, Al₂O₃, or MnO₃ mounted in or on the abrasive polishing pad.
